(19) United States
(12) Patent Application Publication
(10) Pub. No.: US 2004/0161952 A1
(43) Pub. Date: Aug. 19, 2004

(54) Digital card linker

(75) Inventor: Chien-Yuan Chen, (US)

Correspondence Address: TROXELL LAW OFFICE PLLC, SUITE 1404, 5205 LEESBURG PIKE, FALLS CHURCH, VA, 22041, US

(73) Assignee: Power Data Communication Co., Ltd.

(21) Appl. No.: 10/366,511

(22) Filed: Feb. 14, 2003

(51) Int. Cl. H05K 1/00; H01R 12/00

(52) U.S. Cl. 439/59

(57) ABSTRACT

The present invention: digital card linker, especially relates to a linker structure for digital card linking with computer, which is in shape of box; one end of the linker is open end having an open for digital card inserting into. The linker has flexible piece on the upper side and lower side relative to the position of upper and lower terminals of digital card. The digital card linker can be applied to the tradition type digital cards and can be applied to future double faces and single row of digital cards, and can increase the stability of link of linker and digital card.

### BACKGROUND OF THE INVENTION

1. Field of The Invention

The present invention: digital card linker especially, relates to a linker structure for digital card linking with computer.

The digital card linker can be applied to the tradition type digital cards and can be applied to future double faces and single row of digital cards, and can increase the stability of link of linker and digital card.

2. Description of Related Art

Digital card is new pet of new storage media, the volume of which is light, thin, short and small, and which has the character of high compatibility, low cost, large storage capacity, high transfer velocity and security. The digital card adopts open structure and can be applied to mobile telephone, PDA, computer, and various information storage and transfer of media.

Because the effect of the digital card is gradually powerful, the conduct piece that connected with computer for transferring signal is not enough powerful. Because of the volume of said digital card is small, the figure has been and circulate on the market, if straiten the area of the conduct piece to increase the room in which set the conduct pieces will decrease the stability of transfer the signal because of the decrease of area of the conduct piece. Only in the premise that the area of the conduct piece is not changed, increase the number of the conduct piece, that the link of the gradually powerful digital card and the computer will be fulfilled.

So, the present inventor worked out a digital card having terminals on the two sides of digital card that use the double face and single row of flexible pieces to increase the number of the conduct piece. Said digital card use the gradually powerful digital card and at the same time use various conduct piece to link with computer to transfer signal to increase the effect of the digital card.

### SUMMARY OF THE INVENTION

So, the main object of the present invention is to provide a digital linker connecting with computer by said digital card, especially provides a linker structure for digital card connecting with computer. The outline of the linker structure is box. One end of the linker is open end having an open for digital card inserting into. The upper, lower sides of the linker have flexible piece relative to the terminal end of the digital card. The digital card linker can be applied in up-to-date type digital and can be applied in the future double faces single row of digital cards.

Another object of the present invention is to provide a digital card linker that use the flexible pieces on the two sides to hole the digital card at the same time to increase the ability of link of linker and digital card after he digital insert into.

The other objects and detail structure of the present invention will be described in further detail hereinafter, with reference to the accompanying drawings.

As shown in FIG. 1 and FIG. 2, the present invention: digital card linker, especially relates to a linker structure 20 for digital card 10 connecting with computer. The linker comprises a card box 21 and flexible pieces 22, wherein, one end of said card box 21 is open end having an open for digital card inserting into, open end has half groove 23 for digital card 10 inserting into and drawing out, the upper side and lower side has a row of thorough grooves respectively, the corresponding position of thorough grooves is the terminals 11 of digital card 10, the thorough grooves are used for terminals 11 inserting into.

The flexible piece 22 has a contact end 25 that bend inward and a weld end 26 that bend outward. The weld contact end 25 of the flexible piece 22 will protrude into room of card box 21 and weld end 26 of the flexible piece 22 will protrude out form through groove 24 after flexible piece 22 is disposed on thorough groove 24. The structure of the flexible piece is convenient to linker 20 to be welded to circuit board.

### BRIEF DESCRIPTION OF THE DRAWINGS

FIG. 1 is a perspective view of the present invention;

FIG. 2 is a sectional view of the present invention;

FIG. 3 is a combined view of the present invention and digital cards.

FIG. 4 is an enlarged partial view of FIG. 3.

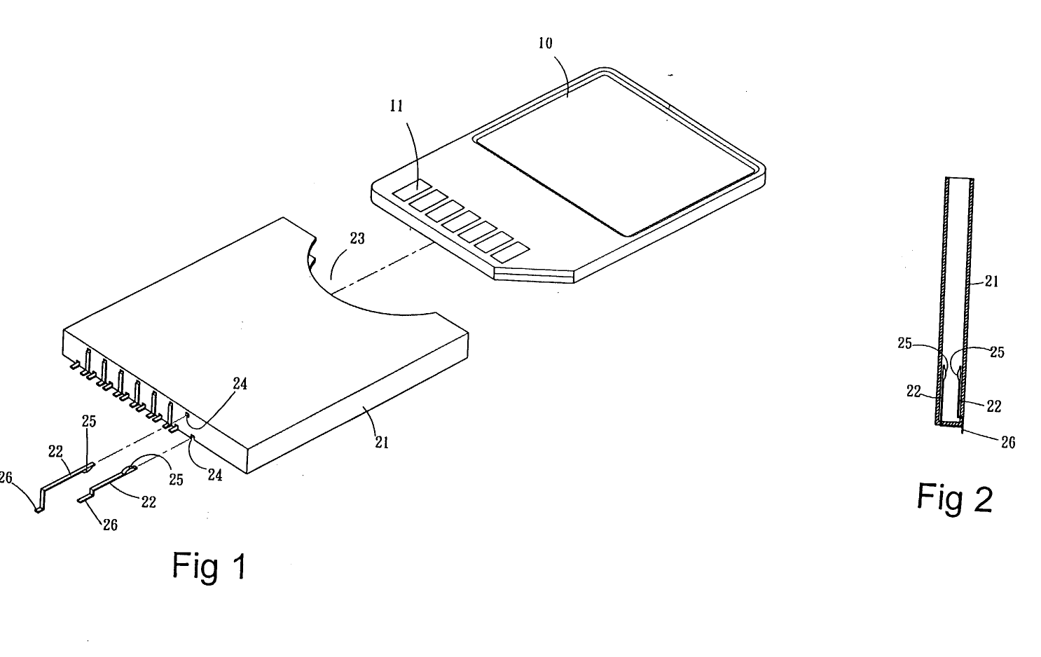

### DETAILED DISCRIPTION OF THE PREFERRED EMBODIMENT

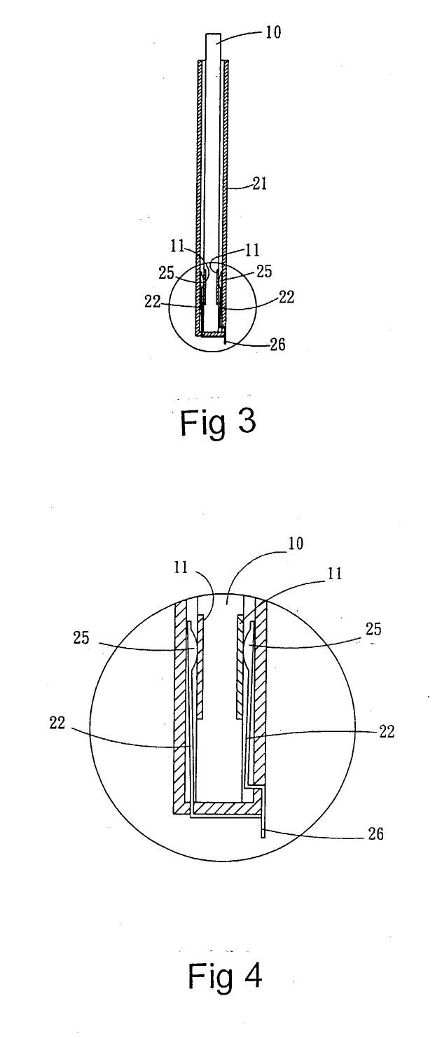

As shown in FIG. 3 and FIG. 4, the flexible piece 22 has good flexibility and the distance between two opposite ends 25 is smaller than the thickness of digital card 10, so when digital card 10 is inserted into the present invention, digital card 10 will against contact end 25 out to make two rows of contact ends 25 produce a hold force engaged on digital card 10 to hold the terminal 11 disposed on digital 10, and to conduct the digital signal of digital 10 besides the effect of hold.

The link of said flexible pieces 22 and card box 21 is not confined in link by thorough grooves 24,of course, the link can use the design of ejecting mold that the flexible piece 22 may be put into mold hole and may be an integrated molding that formed from ejecting molding.

The structure of the present invention may arrange the distance between the flexible pieces 22 and the relative position according to the traditional position. So, the single face single row of digital cards that used popularly can be used, and the new type double faces single row of digital card can be used too, which make the present invention universal in using the new and old digital cards.

The present invention has better hold force because that holds digital card by two rows of flexible pieces, and has the better stability of conduct of signal.

The present invention: digital card linker, which has a simple structure and can be applied to up-to-date type digitals and can be applied in future two sides single row of digital cards. And, the present invention can increase the stability of connect of the link of linker with digital card, which is advanced and complied with the request of filing a patent.

### DESCRIPTION OF THE SYMBOLS

10 digital cards

11 terminals

20 linker

21 card box

22 flexible pieces

23 half groove

24 thorough grooves

25 conduct end

26 weld end

What is claimed is:

1. A digital card linker for connecting digital card with computer comprising: a card box and flexible pieces, one end of said card box is open end having an open for digital card inserting into, wherein,
the upper side and lower side of said card box have a row of thorough grooves respectively for terminal inserting into; said flexible pieces has a conduct end bend inward and a weld end bend outward, conduct end protrude into room of card box and weld end protrude out from thorough groove to make it's convenient to weld linker to circuit board after said flexible is disposed into thorough groove.

2. The digital linker according to claim 1, wherein said flexible pieces are set in the mold hole to be an integrated molding with card box.

3. The digital linker according to claim 1, wherein said open end has half groove.
